(19) United States
(12) Patent Application Publication
(10) Pub. No.: US 2026/0013243 A1
(43) Pub. Date: Jan. 8, 2026

(54) IMAGE SENSOR

(71) Applicant: SAMSUNG ELECTRONICS CO., LTD., Suwon-si (KR)

(72) Inventors: Sanghoon Kim, Suwon-si (KR); Younggu Jin, Suwon-si (KR)

(21) Appl. No.: 19/020,758

(22) Filed: Jan. 14, 2025

(30) Foreign Application Priority Data
Jul. 2, 2024 (KR) 10-2024-0086820

(51) Int. Cl. H10F 39/00

(52) U.S. Cl. CPC H10F 39/8033; H10F 39/8057; H10F 39/806; H10F 39/807

(57) ABSTRACT

Image sensors are provided. In some aspects, an image sensor includes a substrate providing a plurality of pixel regions; and a pixel isolation film formed on the substrate and isolating the plurality of pixel regions from each other. Each pixel region includes a first impurity region, a second impurity region, a first well region, a second well region, and a third well region. The pixel regions include a first pixel region and a second pixel region. At least one of structural properties of the first pixel region is different from that of the second pixel region. The structural properties include a doping concentration and a thickness of the first well region, a doping concentration of the second well region, a surface area of a light-receiving surface, and the presence and a volume of a device isolation film disposed between the first impurity region and the second impurity region.

### CROSS-REFERENCE TO RELATED APPLICATION(S)

This application claims benefit of priority to Korean Patent Application No. 10-2024-0086820 filed on Jul. 2, 2024, in the Korean Intellectual Property Office, the disclosure of which is incorporated herein by reference in its entirety.

### BACKGROUND

An image sensor has been applied in various fields beyond simply photographing a subject and creating a two-dimensional image, such as measuring a distance to the subject or creating a three-dimensional image. Particularly, research on an image sensor using a single photon avalanche diode (SPAD) has been actively conducted recently to accurately and swiftly measure a distance to a subject.

### SUMMARY

In some implementations, the present disclosure provides an image sensor in which at least a portion of diodes included in a plurality of pixel regions may respond to light of different intensities, and may have improved high dynamic range (HDR) performance by varying a doping concentration and a thickness of a well region, a surface area of a light-receiving surface, and a volume of a device isolation film included in a plurality of pixel regions.

According to some implementations of the present disclosure, an image sensor includes a substrate providing a plurality of pixel regions; and a pixel isolation film formed on the substrate and isolating the plurality of pixel regions from each other, wherein each of the plurality of pixel regions includes a first impurity region doped with impurities of a first conductivity-type, a second impurity region surrounding the first impurity region and doped with impurities of a second conductivity-type different from the first conductivity-type, a first well region disposed below the first impurity region and doped with impurities of the first conductivity-type, a second well region disposed below the second impurity region and doped with impurities of the second conductivity-type, and a third well region disposed below the second well region and doped with impurities of the second conductivity-type, wherein the plurality of pixel regions include a first pixel region and a second pixel region adjacent to the first pixel region, and at least one of a doping concentration and a thickness of the first well region, a doping concentration of the second well region, a surface area of the light-receiving surface formed on one surface of the substrate, and the presence and a volume of the device isolation film disposed between the first impurity region and the second impurity region of the first pixel region is different from a doping concentration and a thickness of the first well region, a doping concentration of the second well region, a surface area of the light-receiving surface formed on one surface of the substrate, and the presence and a volume of the device isolation film disposed between the first impurity region and the second impurity region of the second pixel region, respectively.

According to some implementations of the present disclosure, an image sensor includes a pixel array providing a plurality of pixel regions, wherein the pixel array includes a first pixel region group having a first sensitivity among the plurality of pixel regions and including a plurality of first pixel regions adjacent to each other; a second pixel region group disposed adjacently to the first pixel region group and having a second sensitivity higher than the first sensitivity among the plurality of pixel regions and including a plurality of second pixel regions adjacent to each other; and a third pixel region group disposed adjacently to the first pixel region group and having a third sensitivity lower than the first sensitivity among the plurality of pixel regions and including a plurality of third pixel regions adjacent to each other.

According to some implementations of the present disclosure, an image sensor includes a pixel array providing a plurality of pixel regions; and a peripheral circuit configured to drive the pixel array, wherein the plurality of pixel regions include first pixel regions each including a first diode configured to generate electric charges in response to light of a first intensity; second pixel regions each including a second diode configured to generate electric charges in response to light of a second intensity stronger than the first intensity; and third pixel regions each including a third diode configured to generate electric charges in response to light of a third intensity weaker than the first intensity, wherein the peripheral circuit generates image data using electric charges generated during a single frame period in the first pixel regions, the second pixel regions, and the third pixel regions.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a block diagram illustrating an example image sensor;

FIG. 2 is a circuit diagram illustrating a pixel included in an example image sensor;

FIGS. 3 and 4 are diagrams illustrating an example partial region of a pixel array included in an image sensor;

FIG. 5 is a diagram illustrating an example partial region of a pixel array included in an image sensor;

FIGS. 6 to 10 are cross-sectional diagrams taken along line I-I′ in FIG. 5;

FIG. 11 is a diagram illustrating an example partial region of a pixel array included in an image sensor;

FIG. 12 is a diagram illustrating an example partial region of a pixel array included in an image sensor;

FIG. 13 is a cross-sectional diagram taken along line II-II′ in FIG. 12;

FIG. 14 is a diagram illustrating an example partial region of a pixel array included in an image sensor;

FIG. 15 is a cross-sectional diagram taken along line III-III′ in FIG. 14;

FIG. 16 is a diagram illustrating an example partial region of a pixel array included in an image sensor;

FIGS. 17 and 18 are cross-sectional diagrams taken along line IV-IV′ in FIG. 16;

FIG. 19 is a diagram illustrating an example partial region of a pixel array included in an image sensor;

FIG. 20 is a cross-sectional diagram taken along line V-V′ in FIG. 19;

FIG. 21 is a diagram illustrating an example partial region of a pixel array included in an image sensor;

FIG. 22 is a cross-sectional diagram taken along line VI-VI′ in FIG. 21;

FIG. 23 is a diagram illustrating an example partial region of a pixel array included in an image sensor; and

FIG. 24 is a cross-sectional diagram taken along line VII-VII′ in FIG. 23.

### DETAILED DESCRIPTION

Hereinafter, implementations of the present disclosure will be described as follows with reference to the accompanying drawings.

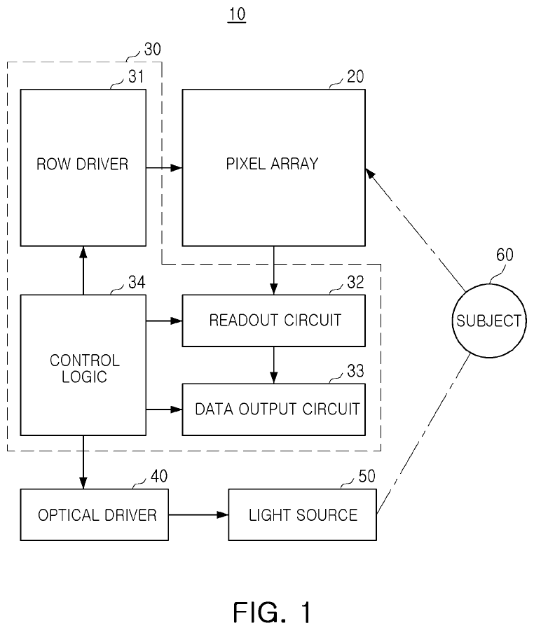

FIG. 1 is a block diagram illustrating an image sensor according to some implementations. Referring to FIG. 1, the image sensor 10 may include a pixel array 20, a peripheral circuit 30, an optical driver 40, and a light source 50. The pixel array 20 may include a plurality of pixels disposed in an array form along a plurality of rows and a plurality of columns. Each of the plurality of pixels may include at least one photoelectric conversion device configured to generate electric charges in response to light. The photoelectric conversion device may be a diode formed of a semiconductor material, and as an example, the diode may be a single photon avalanche diode which may cause a photon avalanche effect.

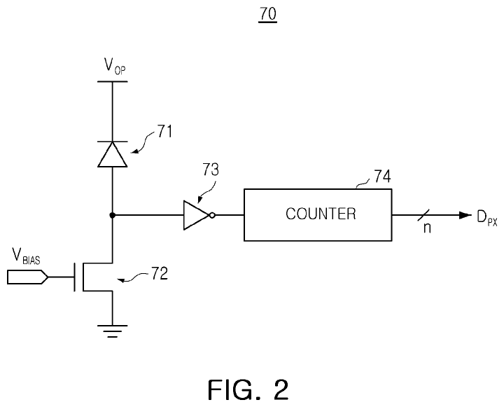

Each of the plurality of pixels may further include a pixel circuit configured to generate a pulse signal based on an electrical signal generated by a photon incident to the diode, in addition to the diode. In some implementations, the pixel circuit may include a transistor, a pulse generator, and a counter connected to the diode. The configuration and operation of the pixel circuit will be described later with reference to FIG. 2.

The peripheral circuit 30 may include circuits for controlling the pixel array 20. For example, the peripheral circuit 30 may include a row driver 31, a readout circuit 32, a data output circuit 33, and a control logic 34. The row driver 31 may drive the pixel array 20 in units of row lines. For example, the row driver 31 may apply a control signal to apply a reverse bias voltage to a single photon avalanche diode to each of the select pixels arranged along a selected row line.

The readout circuit 32 may be connected to the pixels through column lines. The readout circuit 32 may read a pixel signal from pixels connected to a row line selected by a row line select signal of the row driver 31 through the column lines. In some implementations, the pixel signal may be a pulse signal generated by each pixel. The readout circuit 32 may convert the pixel signal into a digital pixel signal and may transfer the signal to the data output circuit 33. The data output circuit 33 may output the digital pixel signal according to a predetermined interface, and for example, the signal output by the data output circuit 33 may be transmitted to an image signal processor (ISP) connected to the image sensor 10.

The control logic 34 may include a timing controller for controlling an operation timing of the row driver 31, the readout circuit 32, and the data output circuit 33. Also, in some implementations, the control logic 34 may control the operation of the optical driver 40 configured to drive the light source 50.

In some implementations, the optical driver 40 may output an optical control signal in the form of a clock signal to the light source 50, and the light source 50 may irradiate light to the subject 60 in response to the optical control signal. The light source 50 may include a laser diode, a light-emitting diode, a near-infrared laser, a point light source, which output light of a specific wavelength band.

Light output by the light source 50 may be reflected from the subject 60 and may be incident to the pixel array 20 by the optical driver 40. For example, one or more lenses may be disposed in a path in which light reflected from the subject 60 may be incident to the pixel array 20. At least one of the plurality of pixels included in the pixel array 20 may generate a pixel signal in response to light reflected from the subject 60.

The image sensor 10 according to some implementations illustrated in FIG. 1 may sense a distance to the subject 60 using a direct time-of-flight (direct ToF) method. The direct ToF method may be a method of calculating a distance to the subject 60 by directly measuring the time from the time point at which light is irradiated to the subject 60 to the time point at which light reflected from the subject 60 is incident.

As described above, the pixel signal output by each of the plurality of pixels may be a pulse signal. The readout circuit 33 may calculate a time delay between a pixel signal output by each of the plurality of pixels and an optical control signal output by the optical driver 40 to the light source 50, and may generate a digital pixel signal based on the time delay. For example, the readout circuit 33 may include a time-to-digital (TDC) circuit which may convert the time delay into a digital signal.

In an image sensor according to some implementations, the pixel array 20 may include a plurality of pixel regions. A portion of the plurality of pixel regions may include diodes configured to respond to light of different intensities. The pixel array 20 may include first pixel regions each including a first diode configured to generate electric charges in response to light of a first intensity, second pixel regions each including a second diode configured to generate electric charges in response to light of a second intensity stronger than the first intensity, and third pixel regions including a third diode configured to generate electric charges in response to light of a third intensity weaker than the first intensity. Since each of the first to third diodes responds to light of different intensities, each of the first to third pixel regions may have different degrees of sensitivity.

The peripheral circuit 30 may generate image data having a high dynamic range (HDR) within a single frame period using pixel signals output by the first to third pixel regions, respectively. The second diode may provide an image of a dark region in response to relatively low illumination, and the third diode may provide an image of a bright region in response to relatively high illumination. Since at least a portion of the plurality of pixel regions may have different degrees of sensitivity, the range of light intensities to which the plurality of pixel regions may respond may be widened, and an image sensor having improved HDR properties may be provided to generate a high-quality image even in a high-contrast environment.

FIG. 2 is a circuit diagram illustrating a pixel included in an image sensor according to some implementations. Referring to FIG. 2, a pixel 70 included in an image sensor according to some implementations may include a diode 71, a transistor 72, a pulse generator 73, and a counter 74. The diode 71 may be a single photon avalanche diode as described above, and may output an electrical signal by generating an avalanche effect by an externally incident photon.

The transistor 72 may provide a quenching circuit configured to limit excess current. For example, as a reverse voltage applied to the diode 71 increases, probability in which thermal electrons are in an excited state and probability of tunneling may increase, and accordingly, dark current flowing due to the avalanche effect may be generated even in a state in which a photon is not incident. The current generated by the avalanche effect due to the photon incident may be added such that the dark current may output excess current, and by turning on the transistor 72 and reducing the reverse voltage of the diode 71, the avalanche effect may be stopped.

The pulse generator 73 may convert an electrical signal corresponding to the current flowing through the diode 71 into a pulse signal, and may include an inverter, for example. An operation voltage Vop may be applied to a cathode of the diode 71, and when the operation voltage Vop is greater than a breakdown voltage of the diode 71, the current generated by the avalanche effect may be input to the pulse generator 73.

The period of the pulse signal generated by the pulse generator 73 may be varied depending on surrounding illumination. For example, the period of the pulse signal may be varied by an electrical signal generated by the diode 71 and a control signal determined depending on a surrounding illumination value. In some implementations, the period of the pulse signal may increase as the surrounding illumination increases. For example, the pulse generator 73 may output a pulse signal determined by a logic level of “0” or “1” depending on whether the current generated by the diode 71 is equal to or greater than a threshold level.

The counter 74 may count a pulse signal and may output an n-bit digital pixel signal (Dpx). In example implementations, the counter 74 may be provided for each pixel, or may be included in the readout circuit.

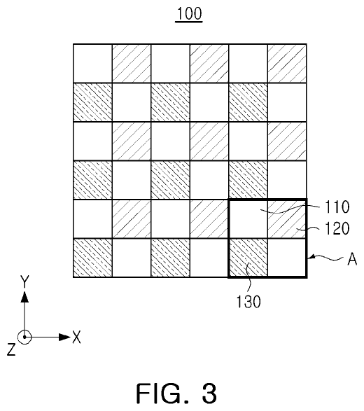

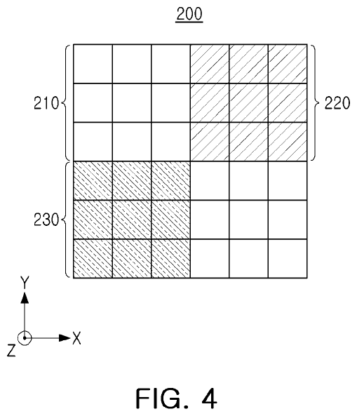

FIGS. 3 and 4 are diagrams illustrating a partial region of a pixel array included in an image sensor according to some implementations. Referring to FIG. 3, a pixel array 100 of an image sensor according to some implementations may include a plurality of pixel regions. The plurality of pixel regions may include a first pixel region 110, a second pixel region 120 and a third pixel region 130 adjacent to the first pixel region 110. By configuring the second pixel region 120 to have a structure different from the first pixel region 110, the second pixel region 120 may have sensitivity higher than sensitivity of the first pixel region 110, and by configuring the third pixel region 130 to have a structure different from the first pixel region 110, the third pixel region 130 may have sensitivity lower than sensitivity of the first pixel region 110.

Sensitivity may be defined as indicating intensity of light required to generate a current in a diode disposed in each of the plurality of pixel regions. For example, a diode in the second pixel region 120 having high sensitivity may generate a current in response to light of relatively low intensity, and a diode in the third pixel region 130 having low sensitivity may generate a current in response to light of relatively high intensity.

Each of the plurality of pixel regions may include a first impurity region defined on the substrate and doped with the first conductivity-type, a second impurity region surrounding the first impurity region and doped with a second conductivity-type different from the first conductivity-type, a first well region disposed under the first impurity region and doped with the first conductivity-type, and a second well region disposed below the second impurity region and doped with the second conductivity-type. Also, in example implementations, at least a portion of the plurality of pixel regions may include a device isolation film disposed between the first impurity region and the second impurities. Also, in some implementations, each of the plurality of pixel regions may be disposed on a light-receiving surface on which light is incident to the substrate and may include a light shielding portion configured to block at least a portion of the light, and an opening region configured to allow light to pass through may be formed in the light shielding portion in each of the plurality of pixel regions.

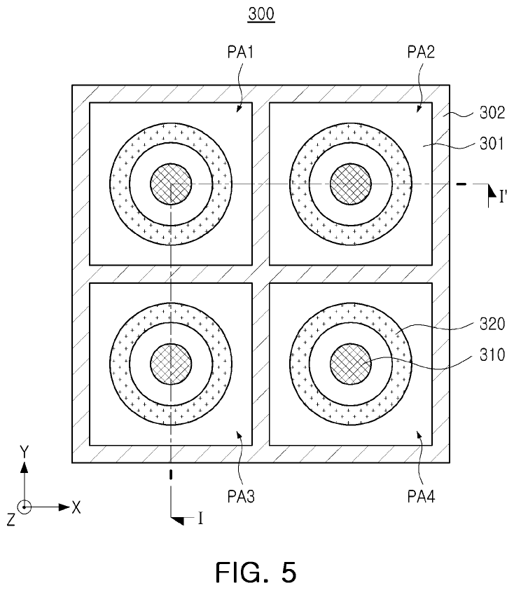

In some implementations, the configuration in which the structures are different may indicate that at least one of a doping concentration and a thickness in the first direction (Z-axis direction) of the first well region, a doping concentration of the second well region, a surface area of the light-receiving surface, the presence and the volume of the device isolation film, and the number of the opening regions respectively included in each of the first to third pixel regions 110-130 may be configured differently. The structure of the pixel region will be described in detail below with reference to FIG. 5.

The pixel array 100 may be arranged in a certain pattern with two first pixel regions 110, one second pixel regions 120, and one third pixel regions 130. For example, the pixel array 100 may include a plurality of pixel region groups A, and one pixel region group A may include two first pixel regions 110, one second pixel regions 120, and one third pixel regions 130.

In the pixel region group A, the two first pixel regions 110 may be disposed in a diagonal direction. Each of the second pixel region 120 and the third pixel region 130 may be adjacent to the first pixel regions 110 in the X-axis direction and the Y-axis direction. The plurality of pixel regions included in the pixel array 100 may include a third pixel region 130 having low sensitivity and a second pixel region 120 having high sensitivity, such that at least a portion of the first to third pixel regions 110-130 may generate current in response to light of different intensities. Accordingly, high dynamic range (HDR) performance of the image sensor may be improved to generate a high-quality image even in a high-contrast environment.

However, a pixel region group A disposed in a certain pattern in the pixel array 100 is not limited to four pixel regions 110-130 disposed in a 2×2 form. For example, the pixel regions 110-130 included in the pixel region group A may be disposed in various forms such as 1×3, 1×4, 3×3, and 4×4. In example implementations, sensitivity of pixel regions included in the pixel region group A may be classified into three or more levels.

Referring to FIG. 4, the pixel array 200 of the image sensor according to some implementations may include pixel region groups 210-230 in which several adjacent pixel regions are grouped. The number of pixel regions included in each of the pixel region groups 210-230 may be 4, 9, and 16, and each of the pixel regions may include a diode.

The diodes included in each of the pixel region groups 210-230 may be grouped and may operate simultaneously. For example, in some implementations illustrated in FIG. 4, an anode and a cathode of the 9 diodes included in each of the pixel region groups 210-230 may be connected to each other. Accordingly, each of the pixel region groups 210-230 may function as a single large pixel, such that image quality may improve in a low-illumination environment with low light intensity, and object recognition may be supported under various degrees of illumination.

At least a portion of the plurality of pixel region groups may have different degrees of sensitivity. For example, the first pixel region group 210 may include a plurality of first pixel regions having first sensitivity and adjacent to each other. The second pixel region group 220 may include a plurality of second pixel regions adjacent to each other, having a second sensitivity higher than the first sensitivity, and may disposed adjacent to the first pixel region group 210. The third pixel region group 230 may include a plurality of third pixel regions adjacent to each other, having a third sensitivity lower than the first sensitivity, and may be disposed adjacent to the first pixel region group. In the pixel array 200, the number of the plurality of first pixel regions may be greater than the number of the plurality of second pixel regions or the number of the plurality of third pixel regions.

To configure degrees of sensitivity of the pixel regions included in the first to third pixel region groups to be different from each other, at least one of structural properties may be configured to different. The structural properties may include a doping concentration and a thickness of the first well region, a doping concentration of the second well region, a surface area of the light-receiving surface, the presence and volume of the device isolation film, and the number of opening regions included in the pixel region.

For example, in each of the plurality of second pixel regions included in the second pixel region group 220, the first well region may be doped with a doping concentration higher than a doping concentration of each of the plurality of first pixel regions included in the first pixel region group 210, and a thickness of the first well region may be increased in the first direction than a thickness of the first well region of each of the plurality of first pixel regions included in the first pixel region group 210. Accordingly, the plurality of second pixel regions having the second sensitivity may output an electrical signal in response to illumination lower than that of the plurality of first pixel regions having the first sensitivity.

Since at least a portion of a plurality of pixel regions included in the pixel array 200 may have different degrees of sensitivity, diodes included in at least a portion of the pixel regions may react to light of different intensities. Accordingly, the range of light intensities to which a plurality of pixel regions may react may be widened, and an image sensor having improved HDR performance may be provided to generate high-quality images even in environments with high contrast.

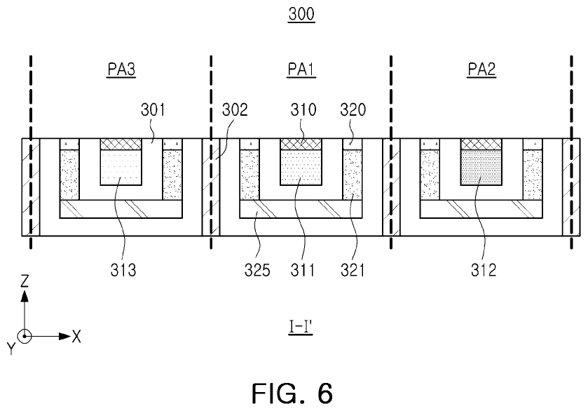

FIG. 5 is a diagram illustrating a partial region of a pixel array included in an image sensor according to some implementations. FIGS. 6 to 10 are cross-sectional diagrams taken along line I-I′ in FIG. 5.

Referring to FIGS. 3 and 5, a partial region 300 of a pixel array may be a pixel region group A. The pixel array 300 of an image sensor according to some implementations may include a plurality of pixel regions PA1-PA4. The plurality of pixel regions PA1-PA4 may be isolated from each other by a pixel isolation film 302 formed on a substrate 301, and may be arranged in directions parallel to an upper surface of the substrate 301.

In each of the plurality of pixel regions PA1-PA4, the first impurity region 310 and the second impurity region 320 providing diodes included in the pixel region may be disposed. The first impurity region 310 may be doped with impurities of a first conductivity-type, and the second impurity region 320 may be doped with impurities of a second conductivity-type different from the first conductivity-type. In some implementations, the first impurity region 310 may be doped with P-type impurities, and the second impurity region 320 may be doped with N-type impurities. In this case, the first impurity region 310 may provide an anode of diode, and the second impurity region 320 may provide a cathode of diode.

Referring to FIG. 6, well regions 311, 321, and 325 may be formed below each of the first impurity region 310 and the second impurity region 320 in the first direction (Z-axis direction) perpendicular to an upper surface of the substrate 301. A first well region 311 doped with impurities of the first conductivity-type may be formed below the first impurity region 310, a second well region 321 doped with impurities of the second conductivity-type may be formed below the second impurity region 320, and a third well region 325 doped with impurities of the second conductivity-type may be formed below the second well region 321. The first impurity region 310 may have a thickness smaller than that of the first well region 311 in the first direction, the second impurity region 320 may have a thickness smaller than that of the second well region 321 in the first direction, and the third well region 325 may have a thickness smaller than that of the second well region 321 in the first direction.

The plurality of pixel regions may include a first pixel region PA1, a second pixel region PA2 and a third pixel region PA3 adjacent to the first pixel region PA1. The doping concentrations of the first well regions 311, 312, and 313 included in the first pixel region PA1, the second pixel region PA2, and the third pixel region PA3, respectively, may be different. As the doping concentration of the first well region 311-313 increases, the diode included in the pixel region may generate a current at relatively low illumination, such that sensitivity of the pixel region may increase.

The doping concentration of the first well region 312 included in the second pixel region PA2 may be higher than the doping concentration of the first well region 311 included in the first pixel region PA1. The doping concentration of the first well region 311 included in the first pixel region PA1 and the doping concentration of the first well region 312 included in the second pixel region PA2 may have a difference of 10% to 20%.

By doping the first well region 312 included in the second pixel region PA2 in a doping concentration higher than that of the first well region 311 included in the first pixel region PA1, the second pixel region PA2 may be formed to have sensitivity higher than that of the first pixel region PA1. Accordingly, the diode included in the second pixel region PA2 may output an electrical signal by responding to low illumination to which the diode included in the first pixel region PA1 does not respond. The thickness of the first well region 311 included in the first pixel region PA1 and the thickness of the first well region 312 included in the second pixel region PA2 may be substantially the same in the first direction. The first direction can be Z direction of FIG. 6.

The doping concentration of the first well region 313 included in the third pixel region PA3 may be lower than the doping concentration of the first well region 311 included in the first pixel region PA1. The doping concentration of the first well region 311 included in the first pixel region PA1 and the doping concentration of the first well region 313 included in the third pixel region PA3 may have a difference of 10% to 20%.

By doping the first well region 313 included in the third pixel region PA3 in a doping concentration lower than that of the first well region 311 included in the first pixel region PA1, the third pixel region PA3 may be formed to have sensitivity lower than that of the first pixel region PA1. Accordingly, the diode included in the third pixel region PA3 may output an electrical signal by only responding to illumination higher than illumination responding to the diode included in the first pixel region PAL. The thickness of the first well region 311 included in the first pixel region PA1 and the thickness of the first well region 313 included in the second pixel region PA2 may be substantially the same in the first direction.

As mentioned above, at least a portion of the plurality of pixel regions PA1-PA4 included in the pixel array 300 may have different degrees of sensitivity. The diode included in the second pixel region PA2 may respond to relatively low illumination and may provide an image of a dark region, and the diode included in the third pixel region PA3 may respond to relatively high illumination and may provide an image of a bright region. Accordingly, the intensity range of light to which the plurality of pixel regions PA1-PA4 may respond may be widened. When the degrees of sensitivity of at least a portion of the plurality of pixel regions PA1-PA4 are configured differently, an image sensor have improved HDR properties may be provided to generate a high-quality image even in a high-contrast environment.

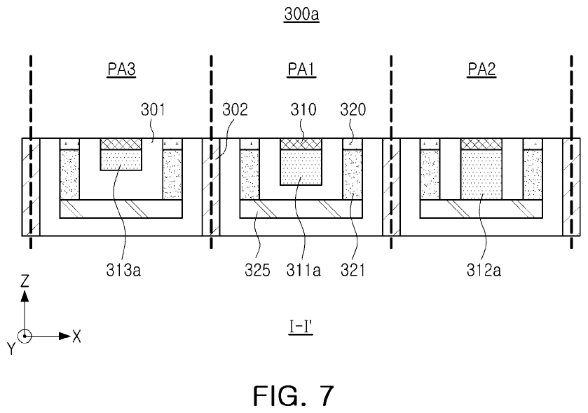

Referring to FIG. 7, the thicknesses of the first well regions 311a, 312a, and 313a included in the first pixel region PA1, the second pixel region PA2, and the third pixel region PA3, respectively, may be different in the first direction. The thickness of the first well region 312a included in the second pixel region PA2 may be greater than the thickness of the first well region 311a included in the first pixel region PA1. A distance between the first well region 312a and the third well region 325 included in the second pixel region PA2 may be closer than a distance between the first well region 311a and the third well region 325 included in the first pixel region PA1, more current may flow in the second pixel region PA2 than in the first pixel region PA1. In this case, the doping concentration of the first well region 311a included in the first pixel region PA1 may be substantially the same as the doping concentration of the first well region 312a included in the second pixel region PA2.

In some implementations, a portion of the first well region 312a of the second pixel region PA2 may be in contact with a portion of the third well region 325. In a reverse bias state in which a relatively low voltage is applied to the first impurity region 310 and a relatively high voltage is applied to the second impurity region 320, when a photon is incident from an external entity, an electrical signal may be output by the avalanche effect at a contact surface between the first well region 312a and the third well region 325. The pixel region PA2 in which the first well region 312a and the third well region 325 are in contact with each other may react to weak incident light as more current flows therethrough than in the pixel regions PA1 and PA3 in which the first well region and the third well region are not in contact with each other. Accordingly, the second pixel region PA2 may have sensitivity higher than that of the first pixel region PA1.

The thickness of the first well region 313a included in the third pixel region PA3 may be smaller than the thickness of the first well region 311a included in the first pixel region PA1. Since a distance between the first well region 313a and the third well region 325 included in the third pixel region PA3 is greater than a distance between the first well region 311a and the third well region 325 included in the first pixel region PA1, the diode included in the third pixel region PA3 may output an electrical signal at illumination higher than illumination to which the diode included in the first pixel region PA1 may respond. In this case, the doping concentration of the first well region 311a included in the first pixel region PA1 and the doping concentration of the first well region 313a included in the third pixel region PA3 may be substantially the same.

At least a portion of the plurality of pixel regions PA1-PA4 included in the pixel array 300 may have different degrees of sensitivity. Referring to FIG. 7, in the first direction, the thicknesses of the first well regions 311a-313a included in the plurality of pixel regions PA1-PA4 may be different to have different degrees of sensitivity. The thicknesses of the first well regions 311a-313a included in the plurality of pixel regions PA1-PA4 may be different to have different sensitivities of the plurality of pixel regions PA1-PA4, and accordingly, the intensity range of light to which the plurality of pixel regions PA1-PA4 may respond may be widened. By configuring degrees of sensitivity of at least a portion of a plurality of pixel regions PA1-PA4 differently, an image sensor having improved HDR properties may be provided to generate a high-quality image even in a high-contrast environment.

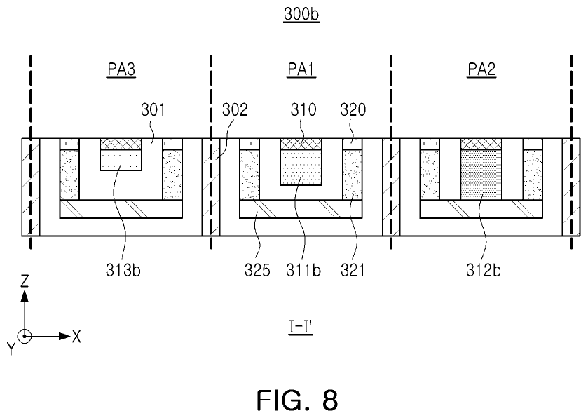

Referring to FIG. 8, doping concentrations and thicknesses in the first direction of the first well regions 311b, 312b, and 313b included in each of the first pixel region PA1, the second pixel region PA2, and the third pixel region PA3 may be different. The doping concentration of the first well region 312b included in the second pixel region PA2 may be more highly doped than the doping concentration of the first well region 311b included in the first pixel region PA1, and the thickness of the first well region 312b included in the second pixel region PA2 may be greater than the thickness of the first well region 311b included in the first pixel region PAL. Accordingly, the diode included in the second pixel region PA2 may output an electrical signal in response to incident light weaker than the diode included in the first pixel region PA1.

The doping concentration of the first well region 313b included in the third pixel region PA3 may be doped lower than the doping concentration of the first well region 311b included in the first pixel region PA1, and the thickness of the first well region 313b included in the third pixel region PA3 may be smaller than the thickness of the first well region 311b included in the first pixel region PAL. Accordingly, the diode included in the third pixel region PA3 may output an electrical signal at illumination higher than the diode included in the first pixel region PA1.

As mentioned above, by configuring doping concentrations and thicknesses of the first well region included in the plurality of pixel regions PA1-PA4 to be different, at least a portion of the plurality of pixel regions PA1-PA4 may have different degrees of sensitivity. Accordingly, the range of light intensity to which the plurality of pixel regions PA1-PA4 may react may be widened, and an image sensor having improved HDR properties may be provided to generate a high-quality image even in a high-contrast environment.

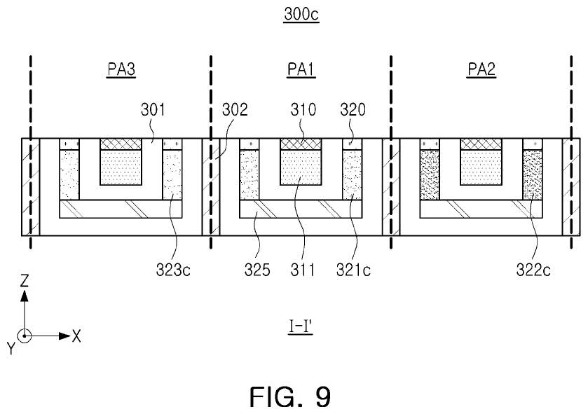

Referring to FIG. 9, the doping concentrations of the second well regions 321c, 322c, and 323c included in the first pixel region PA1, the second pixel region PA2, and the third pixel region PA3, respectively, may be different. The doping concentration of the second well region 322c included in the second pixel region PA2 may be higher than the doping concentration of the second well region 321c included in the first pixel region PAL. In some implementations, the doping concentration of the second well region 321c included in the first pixel region PA1 and the doping concentration of the second well region 322c included in the second pixel region PA2 may have a difference of 10% to 20%. Accordingly, the diode included in the second pixel region PA2 may output an electrical signal even under low illumination to which the diode included in the first pixel region PA1 does not respond.

The doping concentration of the second well region 323c included in the third pixel region PA3 may be lower than the doping concentration of the second well region 321c included in the first pixel region PAL. In some implementations, the doping concentration of the second well region 321c included in the first pixel region PA1 and the doping concentration of the second well region 323c included in the third pixel region PA3 may have a difference of 10% to 20%. Accordingly, the diode included in the third pixel region PA3 may output an electrical signal by responding to illumination higher than illumination to which the diode included in the first pixel region PA1 responds.

As mentioned above, by configuring the doping concentrations of the second well regions included in the plurality of pixel regions PA1-PA4 to be different, at least a portion of the plurality of pixel regions PA1-PA4 may have different degrees of sensitivity. Accordingly, the intensity range of light to which a plurality of pixel regions PA1-PA4 may react may be widened, and an image sensor having improved HDR properties may be provided to generate a high-quality image even in a high-contrast environment.

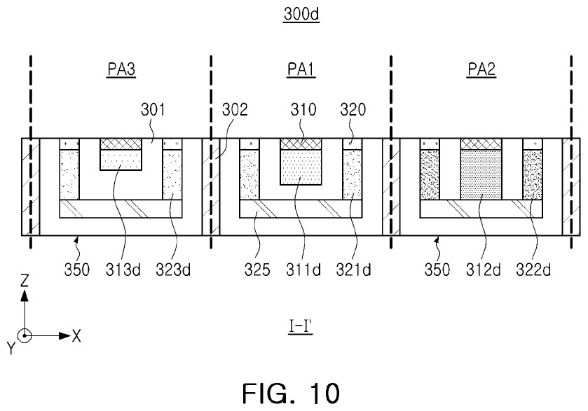

Referring to FIG. 10, doping concentrations and thicknesses in the first direction of the first well regions 311d, 312d, 313d included in the first pixel region PA1, the second pixel region PA2, and the third pixel region PA3, and doping concentrations of the second well regions 321d, 322d, 323d may be different. The first well region 312d and the second well region 322d included in the second pixel region PA2 may be doped in a doping concentration higher than those of the first well region 311d and the second well region 321d included in the first pixel region PAL. The thickness of the first well region 312d included in the second pixel region PA2 may be greater than the thickness of the first well region 311d included in the first pixel region PAL. Accordingly, the second pixel region PA2 may have sensitivity higher than that of the first pixel region PA1, and the diode included in the second pixel region PA2 may output an electrical signal by responding to low illumination to which the diode included in the first pixel region PA1 does not respond.

Each of the first well region 313d and the second well region 323d included in the third pixel region PA3 may be doped with a doping concentration lower than that of the first well region 311d and the second well region 321d included in the first pixel region PAL. The thickness of the first well region 313d included in the third pixel region PA3 may be less than the thickness of the first well region 311d included in the first pixel region PA1. Accordingly, the third pixel region PA3 may have sensitivity lower than that of the first pixel region PA1, such that the diode included in the third pixel region PA3 may output an electrical signal by responding to illumination higher than illumination to which the diode included in the first pixel region PA1 responds.

By configuring the doping concentrations of the first and second well regions 311d-313d and 321d-323d included in the plurality of pixel regions PA1-PA4 to be different and configuring the thicknesses of the first well region 311d-313d to be different, at least a portion of the plurality of pixel regions PA1-PA4 may have different degrees of sensitivity. Accordingly, the intensity range of light to which the plurality of pixel regions PA1-PA4 may respond may be widened, and an image sensor having improved HDR properties may be provided to generate a high-quality image even in a high-contrast environment.

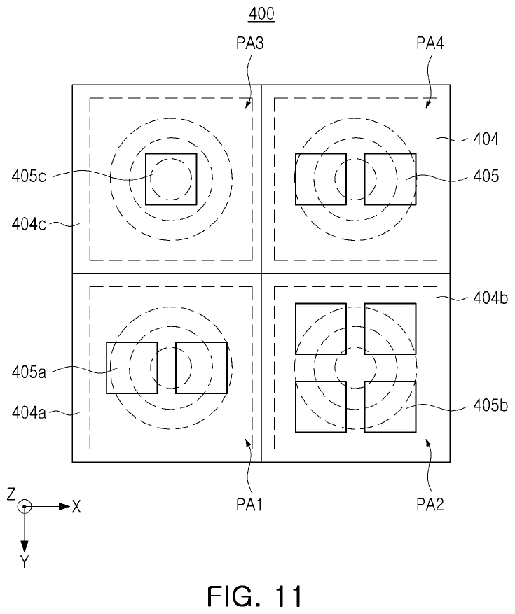

FIG. 11 is a diagram illustrating a partial region of a pixel array included in an image sensor according to some implementations. Referring to FIG. 11, a plurality of pixel regions included in an image sensor according to some implementations may include a light shielding portion 404 and an opening region 405. The light shielding portion 404 may be disposed on a lower surface of the substrate and may block light reaching the pixel region through the lower surface, and the opening region 405 may transmit light reaching the pixel region. The lower surface of the substrate may be the lower surface 350 of the substrate 301 in the negative Z direction, as illustrated in FIG. 10. The numbers of opening regions 405 included in at least a portion of the plurality of pixel regions may be different, such that the degrees of intensity of light reaching the plurality of pixel regions may be different. Accordingly, even when light of the same intensity is incident to the pixel array 400, only at least a portion of the diodes included in the plurality of pixel regions PA1-PA4 may react.

Referring to FIG. 11, a plurality of pixel regions may include a first pixel region PA1 and a second pixel region PA2 adjacent to the first pixel region PA1. Each of the first pixel region PA1 and the second pixel region PA2 may have a light shielding portion 404 disposed on the lower surface of the substrate. In some implementations, the number of opening regions 405b included in the second pixel region PA2 may be greater than the number of opening regions 405a included in the first pixel region PA1.

In some implementations, the opening region 405 may have a square shape, the number of opening regions 405b included in the second pixel region PA2 may be four, and the number of opening regions 405b included in the first pixel region PA1 may be two. However, the shape and the number of the opening regions 405 are not necessarily limited thereto, and the opening region 405 may have a shape such as a triangular shape, a circular shape, an oval shape, a star shape, a cross shape, a square shape, and the number of opening regions may be five, six, or more.

When light of the same intensity is incident to the plurality of pixel regions PA1-PA4, the number of opening regions 405b included in the second pixel region PA2 may be greater than the number of opening regions 404a included in the first pixel region PA1, such that the intensity of light reaching the second pixel region PA2 may be greater than the intensity of light reaching the first pixel region PA1. Accordingly, the second pixel region PA2 may have sensitivity higher than that of the first pixel region PA1, and the diode included in the second pixel region PA2 may output an electrical signal by responding to low illumination to which the diode included in the first pixel region PA1 does not respond.

The plurality of pixel regions may include a third pixel region PA3 adjacent to the first pixel region PA1. The third pixel region PA3 may have a light shielding portion 404c disposed on the lower surface of the substrate, similarly to the first pixel region PAL. The number of opening regions 405c included in the third pixel region PA3 may be less than the number of opening regions 405a included in the first pixel region PAL. In some implementations, the opening region 405c included in the third pixel region PA3 may have a square shape and may be 1.

When light of the same intensity is incident to a plurality of pixel regions PA1-PA4, the number of opening regions 405c included in the third pixel region PA3 may be less than the number of opening regions 405a included in the first pixel region PA1, such that the intensity of light reaching the third pixel region PA3 may be less than the intensity of light reaching the first pixel region PA1. Accordingly, the third pixel region PA3 may have sensitivity lower than that of the first pixel region PA1, and the diode included in the third pixel region PA3 may output an electrical signal by responding to an illumination higher than the illumination to which the diode included in the first pixel region PA1 responds.

By configuring the number of opening regions 405 differently, at least a portion of the plurality of pixel regions PA1-PA4 included in the pixel array 400 may have different degrees of sensitivity. The diode included in the second pixel region PA2 may respond to relatively low illumination and may provide an image of a dark region, and the diode included in the third pixel region PA3 may respond to relatively high illumination and may provide an image of a bright region. Accordingly, the intensity range of light to which the plurality of pixel regions PA1-PA4 may respond may be widened, and an image sensor having improved HDR properties may be provided to generate high-quality images even in a high-contrast environment.

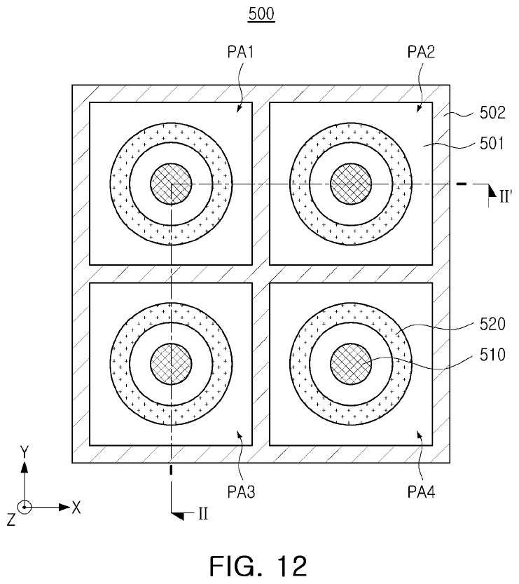

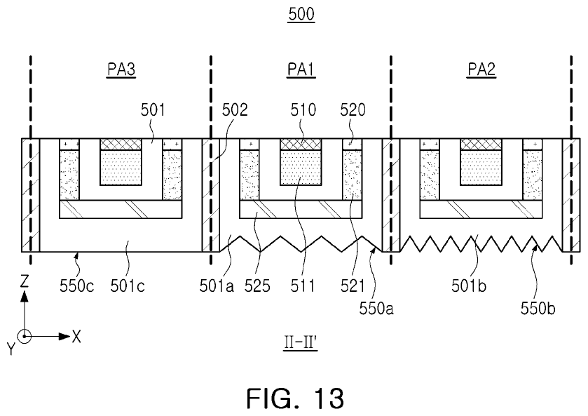

FIG. 12 is a diagram illustrating a partial region of a pixel array included in an image sensor according to some implementations. FIG. 13 is a cross-sectional diagram taken along line II-II′ in FIG. 12.

The plurality of pixel regions PA1-PA4 may include a light-receiving surface on the lower surface of the substrate 501. The light-receiving surface may be disposed on the lower surface of the substrate in the direction in which light is incident, and a portion of the plurality of pixel regions PA1-PA4 may have an uneven profile on the light-receiving surface. When the light-receiving surface has an uneven profile, light incident to the plurality of pixel regions PA1-PA4 may hit the substrate 501 and may be scattered such that a path along which light travels may increase. As the path along which the light travels increases, probability that each of diodes included in the plurality of pixel regions PA1-PA4 absorb light and generate a photon may increase. Accordingly, the diode included in a pixel region having an uneven profile on the light-receiving surface may output an electrical signal even under low illumination conditions to which the diode included in a pixel region not having an uneven profile on the light-receiving surface does not respond.

Referring to FIG. 12 and FIG. 13, a plurality of pixel regions PA1-PA4 may include a first pixel region PA1 and a second pixel region PA2 adjacent to a first pixel region PA1. Each of the first pixel region PA1 and the second pixel region PA2 may have uneven profiles 501a and 501b on the lower surface of the substrate 501, e.g., the light-receiving surface 550a, 550b. In some implementations, the uneven profile 501a, 501b of the substrate may have a beveled shape. However, the uneven profile 501a, 501b of the substrate is not necessarily limited to this shape and may have a quadrangular shape, a polygonal shape, or the like.

The uneven profile 501b included in the second pixel region PA2 may have a surface area wider than that of the uneven profile 501a included in the first pixel region PA1. Since the uneven profile 501b included in the second pixel region PA2 has a surface area wider than that of the uneven profile 501a included in the first pixel region PA1, a traveling path of light incident to the second pixel region PA2 may increase further than a traveling path of light incident to the first pixel region PA1. Accordingly, the diode included in the second pixel region PA2 may have increased probability of generating a photon, and may output an electrical signal by responding to low illumination to which the diode included in the first pixel region PA1 does not respond.

In some implementations, a plurality of pixel regions PA1-PA4 may include a third pixel region PA3 adjacent to the first pixel region PA1. Differently from the first pixel region PA1, the third pixel region PA3 may not have an uneven profile on the lower surface 550c of the substrate 501. Since the third pixel region PA3 does not have an uneven profile, a traveling path of light may not increase, and the diode included in the third pixel region PA3 may output an electrical signal only in response to illumination higher than the diode included in the first pixel region PA1.

At least a portion of the plurality of pixel regions PA1-PA4 included in the pixel array 500 may have different degrees of sensitivity by including the uneven profiles 501a and 501b on the lower surface of the substrate 501. The diode included in the second pixel region PA2 may provide an image of a dark region in response to relatively low illumination, and the diode included in the third pixel region PA3 may provide an image of a bright region in response to relatively high illumination. Accordingly, the intensity range of light to which the plurality of pixel regions PA1-PA4 may respond may be widened, and an image sensor having improved HDR properties may be provided to generate a high-quality image even in a high-contrast environment.

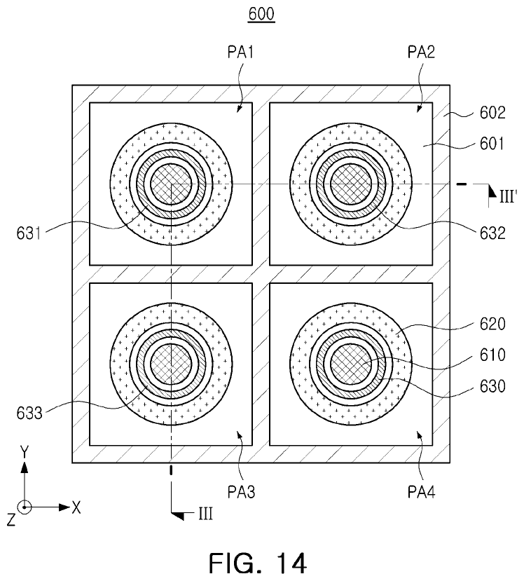

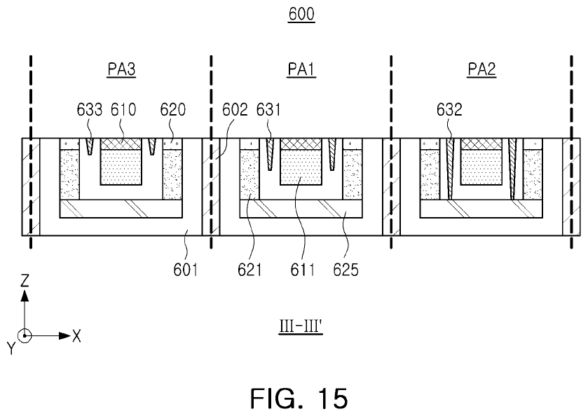

FIG. 14 is a diagram illustrating a partial region of a pixel array included in an image sensor according to some implementations. FIG. 15 is a cross-sectional diagram taken along line III-III′ in FIG. 14. In each of the plurality of pixel regions PA1-PA4, a device isolation film 630 may be disposed between the first impurity region 610 and the second impurity region 620. The device isolation film 630 may be formed of an insulating material, and may include, for example, a plurality of insulating layers, at least a portion of which may be formed of different insulating materials. The device isolation film 630 may be disposed between the first impurity region 610 and the second impurity region 620 in a second direction parallel to an upper surface of the substrate 601, and in some implementations illustrated in FIGS. 14 and 15, the second direction may be defined as a direction away from a center of the first impurity region 610. For example, the second direction may be in the X-Y plane of FIG. 14.

In some implementations, by disposing the device isolation film 630 between the first impurity region 610 and the second impurity region 620, insulating properties between the first impurity region 610 and the second impurity region 620 may be improved. Accordingly, by forming the device isolation film 630, breakdown voltage properties of the diode may be improved, and performance of the image sensor may be improved to obtain a clear image even under low illumination by maximizing the avalanche effect due to the photons flowing thereto.

As illustrated in FIG. 15, the thickness of the device isolation film 631, 632, 633 in the first direction may be different for each pixel region. The device isolation film 631, 632, 633 may be generally referred to as the device isolating film 630 in the present disclosure. The thickness of the device isolation film 630 may be greater than the thickness of each of the first impurity region 610 and the second impurity region 620 in the first direction (e.g., Z direction). In some implementations, the thickness of the device isolation film 632 included in the second pixel region PA2 may be greater than the thickness of the device isolation film 631 included in the first pixel region PA1. A thickness of the device isolation film 631 included in the first pixel region PA1 may be less than the sum of the thicknesses of the first impurity region 610 and the first well region 611, and a thickness of the device isolation film 632 included in the second pixel region PA2 may be greater than the sum of the thicknesses of the first impurity region 610 and the first well region 611. In some implementations, the device isolation film 631 included in the first pixel region PA1 may be isolated from the third well region 625, and a portion of the device isolation film 632 included in the second pixel region PA2 may be in contact with a portion of the third well region 625.

Since the thickness of the device isolation film 632 included in the second pixel region PA2 may be greater than the thickness of the device isolation film 631 included in the first pixel region PA1, insulating properties between the first impurity region 610 and the second impurity region 620 of the second pixel region PA2 may be improved as compared to the first pixel region PA1. Accordingly, since the avalanche effect due to the photons flowing into the second pixel region PA2 is improved as compared to the first pixel region PA1, the diode included in the second pixel region PA2 may output an electrical signal even under low illumination to which the diode included in the first pixel region PA1 does not respond, and may provide an image of the dark region. The width of the device isolation film 631 included in the first pixel region PA1 and the width of the device isolation film 632 included in the second pixel region PA2 may be substantially the same in the second direction (e.g., X or Y direction).

In the first direction, the thickness of the device isolation film 633 included in the third pixel region PA3 may be smaller than the thickness of the device isolation film 631 included in the first pixel region PA1. Insulating properties between the first impurity region 610 and the second impurity region 620 included in the third pixel region PA3 may be lower than insulating properties of the first pixel region PA1, and the diode included in the third pixel region PA3 may respond to illumination higher than the illumination to which the diode included in the first pixel region PA1 starts responding, and may provide an image of a bright region. The width of the device isolation film 631 included in the first pixel region PA1 and the width of the device isolation film 633 included in the third pixel region PA3 may be substantially the same in the second direction.

By configuring the device isolation film 630 to have different thicknesses in the first direction in at least a portion of the plurality of pixel regions PA1-PA4 included in the pixel array 600, a portion of pixel regions may have different degrees of sensitivity. Accordingly, the intensity range of light to which the plurality of pixel regions PA1-PA4 may respond may be widened, and an image sensor having improved HDR properties may be provided to generate high-quality images even in a high-contrast environment.

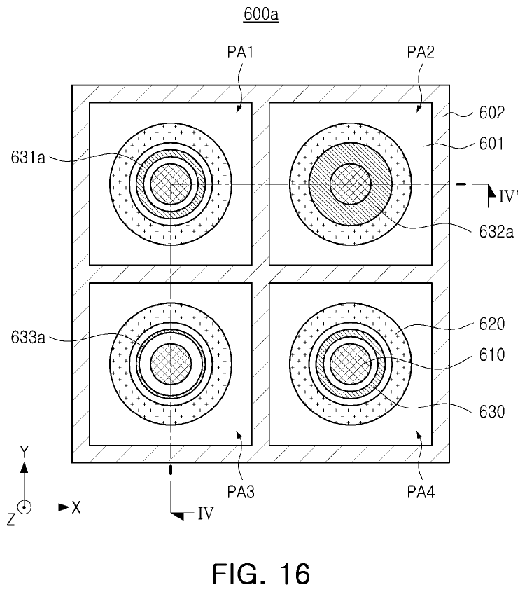

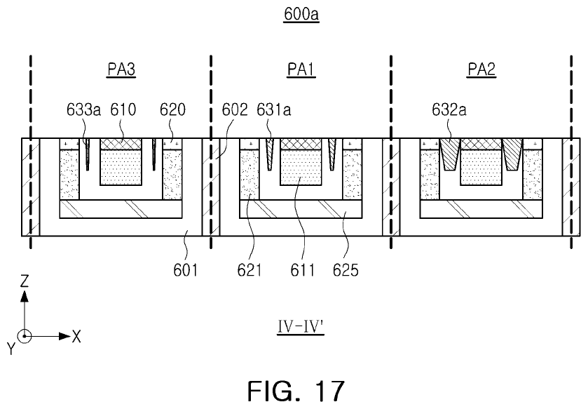

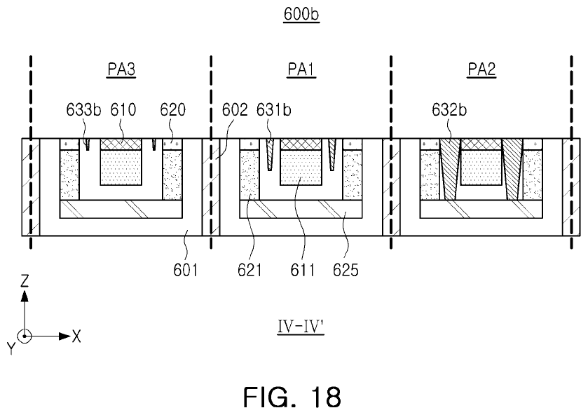

FIG. 16 is a diagram illustrating a partial region of a pixel array included in an image sensor according to some implementations. FIGS. 17 and 18 are cross-sectional diagrams taken along line IV-IV′ in FIG. 16.

In some implementations, at least a portion of a plurality of pixel regions PA1-PA4 may have a device isolation film 630 disposed between the first impurity region 610 and the second impurity region 620. By configuring widths of the device isolation film 630 included in a portion of the pixel regions different from each other in the second direction, the degrees of sensitivity of a portion of pixel regions may be configured to be different.

Referring to FIGS. 16 and 17, a plurality of pixel regions PA1-PA4 may include a first pixel region PA1 and a second pixel region PA2 adjacent to the first pixel region PA1. Each of the first pixel region PA1 and the second pixel region PA2 may have a device isolation film 630 disposed between the first impurity region 610 and the second impurity region 620. The width of the device isolation film 632a included in the second pixel region PA2 may be greater than the width of the device isolation film 631a included in the first pixel region PA1 in the second direction.

In some implementations, one surface of the device isolation film 632a included in the second pixel region PA2 may be in contact with one surface of the first impurity region 610, and the other surface of the device isolation film 632a may be in contact with one surface of the second impurity region 620. Since the width of the device isolation film 632a included in the second pixel region PA2 is greater than the width of the device isolation film 631a included in the first pixel region PA1, insulating properties of the second pixel region PA2 may be improved over insulating properties of the first pixel region PA1, and sensitivity of the second pixel region PA2 may be higher than that of the first pixel region PA1. Accordingly, the diode included in the second pixel region PA2 may provide an image of a dark region by responding to illumination to which the diode included in the first pixel region PA1 does not respond.

The plurality of pixel regions PA1-PA4 may include a third pixel region PA3 adjacent to the first pixel region PA1, and the third pixel region PA3 may include a device isolation film 633a between the first impurity region 610 and the second impurity region 620. The width of the device isolation film 633a included in the third pixel region PA3 may be smaller than the width of the device isolation film 631a included in the first pixel region PA1 in the second direction. Accordingly, insulating properties of the third pixel region PA3 may be degraded as compared to the first pixel region PA1, and the diode included in the third pixel region PA3 may provide an image of a bright region by responding to illumination higher than illumination to which the diode included in the first pixel region PA1 starts to respond.

At least a portion of the plurality of pixel regions PA1-PA4 included in the pixel array 600a may have different widths of the device isolation film 631a-633a in the second direction, such that a portion of the pixel regions may have different degrees of sensitivity. Accordingly, the intensity range of light to which the plurality of pixel regions PA1-PA4 may respond may be widened, and an image sensor having improved HDR properties may be provided to generate high-quality images even in a high-contrast environment.

Referring to FIGS. 16 and 18, volumes of the device isolation film 630 included in at least a portion of the plurality of pixel regions PA1-PA4 may be different from each other. The different volumes of the device isolation film 630 may indicate that the thickness of the device isolation film 630 in the first direction and/or the width of the device isolation film 630 in the second direction may be different. As the volume of the device isolation film 630 increases, insulating properties between the first impurity region 610 and the second impurity region 620 included in the pixel region may be improved, and sensitivity of the pixel region may be increased.

Referring to FIG. 18, the volume of the device isolation film 632b included in the second pixel region PA2 may be greater than the volume of the device isolation film 631b included in the first pixel region PAL. Accordingly, insulating properties of the second pixel region PA2 may be improved as compared to insulating properties of the first pixel region PA1, such that the diode included in the second pixel region PA2 may output an electrical signal by responding to low illumination to which the diode included in the first pixel region PA1 does not respond, and may provide an image of a dark region.

The volume of the device isolation film 633b included in the third pixel region PA3 may be smaller than the volume of the device isolation film 631b included in the first pixel region PA1. Accordingly, insulating properties of the third pixel region PA3 may be lower than insulating properties of the first pixel region PA1, but the diode included in the third pixel region PA3 may respond to higher illumination than the diode included in the first pixel region PA1, and may provide an image of a bright region.

At least a portion of the plurality of pixel regions PA1-PA4 included in the pixel array 600b may have different volumes of the device isolation films 631b-633b, such that a portion of the pixel regions may have different degrees of sensitivity. Accordingly, the range of light intensity to which the plurality of pixel regions may respond may be widened, and an image sensor having improved HDR properties may be provided to generate a high-quality image even in a high-contrast environment.

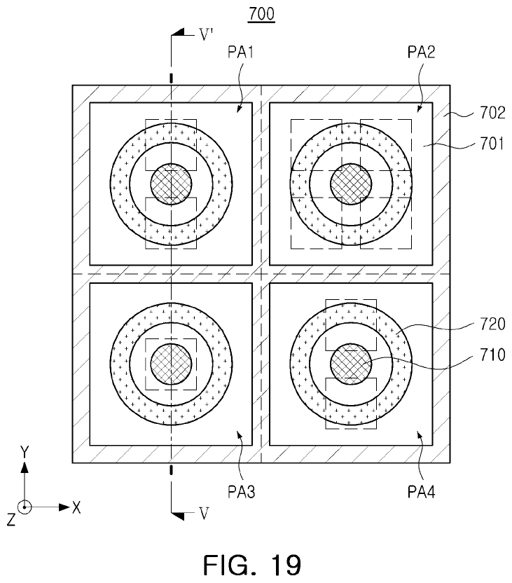

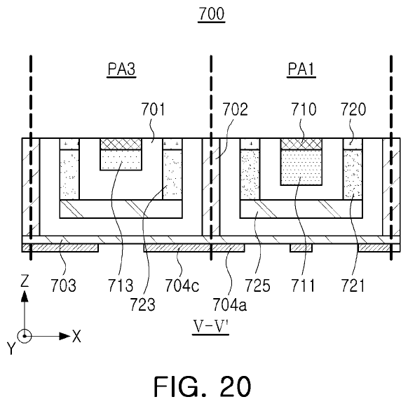

FIG. 19 is a diagram illustrating a partial region of a pixel array included in an image sensor according to some implementations. FIG. 20 is a cross-sectional diagram taken along line V-V′ in FIG. 19.

Referring to FIGS. 19 and 20, a plurality of pixel regions may include a first pixel region PA1 and a third pixel region PA3 adjacent to the first pixel region PA1. The doping concentration and thickness of the first well region 711, the doping concentration of the second well region 721, and the number of opening regions included in the first pixel region PA1 may be different from the doping concentration and thickness of the first well region 713, the doping concentration of the second well region 723, and the number of opening regions included in the third pixel region PA3. Accordingly, the first pixel region PA1 and the third pixel region PA3 may have different degrees of sensitivity.

The number of opening regions included in the first pixel region PA1 may be greater than the number of opening regions included in the third pixel region PA3, and the first well region 711 and the second well region 721 included in the first pixel region PA1 may be doped in a doping concentration higher than that of the first well region 713 and the second well region 723 included in the third pixel region PA3, respectively, and the thickness of the first well region 711 included in the first pixel region PA1 may be greater than the thickness of the second well region 713 included in the third pixel region PA3. Accordingly, the first pixel region PA1 may have sensitivity higher than that of the third pixel region PA3, and the diode included in the first pixel region PA1 may output an electrical signal by responding to low illumination to which the diode included in the third pixel region PA3 does not respond.

At least a portion of a plurality of pixel regions PA1-PA4 included in the pixel array 700 may have different sensitivities by configuring the thickness and the doping concentration of the first well region 711, 713, the doping concentration of the second well region 721, 723, and the number of opening regions to be different. Accordingly, the range of light intensity to which the plurality of pixel regions may respond may be widened, and an image sensor having improved HDR properties may be provided to generate a high-quality image even in a high-contrast environment.

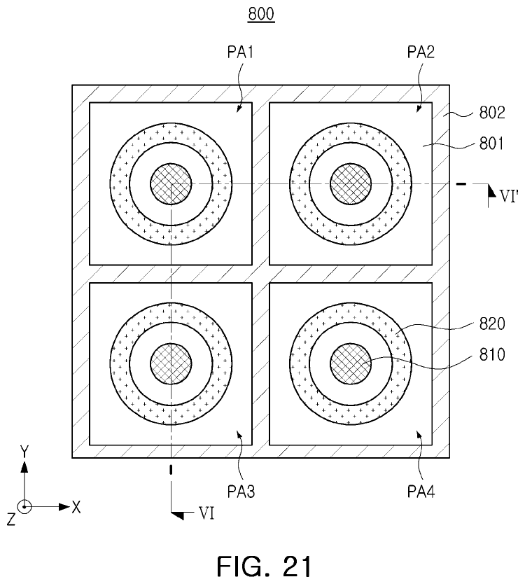

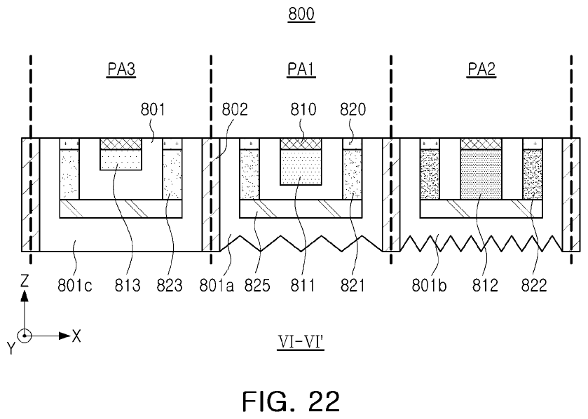

FIG. 21 is a diagram illustrating a partial region of a pixel array included in an image sensor according to some implementations. FIG. 22 is a cross-sectional diagram taken along line VI-VI′ in FIG. 21.

Referring to FIG. 21 and FIG. 22, a plurality of pixel regions may include a first pixel region PA1, a second pixel region PA2 and a third pixel region PA3 adjacent to the first pixel region PAL. Thicknesses and doping concentrations of the first well regions 811, 812, and 813, doping concentrations of the second well regions 821, 822, and 823, and uneven profiles 801a, 801b, and 801c of the substrate 601 respectively included in the first pixel region PA1, the second pixel region PA2, and the third pixel region PA3 may be different. Accordingly, the first pixel region PA1, the second pixel region PA2, and the third pixel region PA3 may have different degrees of sensitivity.

The thickness and the doping concentration of the first well region 812, the doping concentration of the second well region 822, and the surface area of the light-receiving surface 801b included in the second pixel region PA2 may be greater than the thickness and the doping concentration of the first well region 811, the doping concentration of the second well region 821, and the surface area of the light-receiving surface 801a included in the first pixel region PA1, respectively. Accordingly, sensitivity of the second pixel region PA2 may be higher than sensitivity of the first pixel region PA1.

The thickness and the doping concentration of the first well region 813, the doping concentration of the second well region 823, and the surface area of the light-receiving surface 801c included in the third pixel region PA3 may be smaller than the thickness and the doping concentration of the first well region 811, the doping concentration of the second well region 821, and the surface area of the light-receiving surface 801a included in the first pixel region PA1, respectively. Accordingly, sensitivity of the third pixel region PA3 may be lower than sensitivity of the first pixel region PAL. In some implementations, the light-receiving surface 801c included in the third pixel region PA3 may not have an uneven profile.

At least a portion of the plurality of pixel regions PA1-PA4 included in the pixel array 800 may have different degrees of sensitivities by configuring the thicknesses and the doping concentrations of the first well region 811-813, the doping concentrations of the second well region 821-823, and the surface areas of the light-receiving surfaces 801a, 801b, and 801c to be different. Accordingly, the light intensity range to which the plurality of pixel regions may respond may be widened, and an image sensor having improved HDR properties may be provided to generate a high-quality image even in a high-contrast environment.

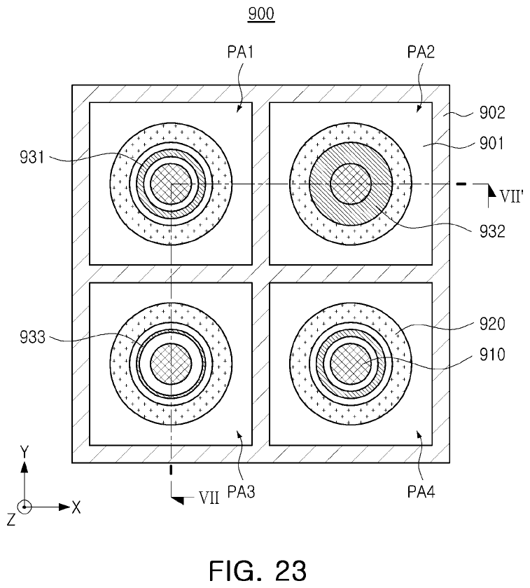

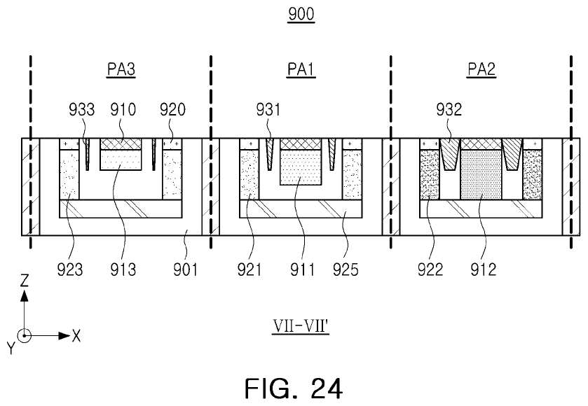

FIG. 23 is a diagram illustrating a partial region of a pixel array included in an image sensor according to some implementations. FIG. 24 is a cross-sectional diagram taken along line VII-VII′ in FIG. 23.

Referring to FIGS. 23 and 24, the first pixel region PA1, the second pixel region PA2, and the third pixel region PA3 may include a device isolation film 931-933, and the widths of the device isolation film 931-933, the thicknesses and doping concentrations of the first well region 912-913, and the doping concentrations of the second well regions 921-923 included in each pixel region PA1-PA4 may be different. Accordingly, the plurality of pixel regions PA1-PA4 may have different degrees of sensitivity. In some implementations, by configuring the volume of the device isolation film 931-933 to be different, the degrees of sensitivity of the pixel regions PA1-PA4 may be different.

The width of the device isolation film 932, the thickness and the doping concentration of the first well region 912, and the doping concentration of the second well region 922 included in the second pixel region PA2 may be greater than the width of the device isolation film 931, the thickness and the doping concentration of the first well region 911, and the doping concentration of the second well region 921 included in the first pixel region PA1, respectively. Accordingly, sensitivity of the second pixel region PA2 may be higher than sensitivity of the first pixel region PA1.

The width of the device isolation film 933, the thickness and the doping concentration of the first well region 913, and the doping concentration of the second well region 923 included in the third pixel region PA3 may be smaller than the width of the device isolation film 931, the thickness and the doping concentration of the first well region 911, and the doping concentration of the second well region 921 included in the first pixel region PA1, respectively. Accordingly, sensitivity of the third pixel region PA2 may be lower than sensitivity of the first pixel region PA1.

At least a portion of the plurality of pixel regions PA1-PA4 included in the pixel array 900 may have different degrees of sensitivities by configuring the thicknesses and the doping concentrations of the first well regions 911-913, the doping concentrations of the second well regions 921-923, and the widths of the device isolation films 831-933 to be different. Accordingly, the intensity range of light to which the plurality of pixel regions may respond may be widened, and an image sensor having improved HDR properties may be provided to generate a high-quality image even in a high-contrast environment.

According to the aforementioned example implementations, at least one of the doping concentrations and thicknesses of the well region included in the pixel region, the surface areas of the light-receiving surface, the volumes of the device isolation film, and the numbers of opening regions of at least a portion of the plurality of pixel regions may be configured differently. By configuring at least a portion of the pixel regions to have different structures, at least a portion of the pixel regions may have different degrees of sensitivity, and at least a portion of diodes included in the plurality of pixel regions may respond to different intensities of light. Since a range of light intensities to which a plurality of pixel regions having different degrees of sensitivity may respond is widened, an image sensor having improved high dynamic range (HDR) performance may be provided to generate a high quality image even in a high contrast environment.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the example implementations have been illustrated and described above, it will be configured as apparent to those skilled in the art that modifications and variations could be made without departing from the scope of the present disclosure as defined by the appended claims.

What is claimed is:

1. An image sensor, comprising:
a substrate comprising a plurality of pixel regions; and
a pixel isolation film formed on the substrate and isolating the plurality of pixel regions from each other,
wherein each of the plurality of pixel regions comprises a first impurity region doped with impurities of a first conductivity-type, a second impurity region surrounding the first impurity region and doped with impurities of a second conductivity-type different from the first conductivity-type, a first well region disposed below the first impurity region and doped with impurities of the first conductivity-type, a second well region disposed below the second impurity region and doped with impurities of the second conductivity-type, and a third well region disposed below the second well region and doped with impurities of the second conductivity-type,
wherein the plurality of pixel regions comprise a first pixel region and a second pixel region adjacent to the first pixel region, and a structural property of the first pixel region has a value that is different from a value of the same structural property of the second pixel region, and
wherein the structural property comprises at least one of a doping concentration and a thickness of the first well region, a doping concentration of the second well region, a surface area of a light-receiving surface formed on a surface of the substrate, or a volume of a device isolation film disposed between the first impurity region and the second impurity region.

2. The image sensor of claim 1, wherein the doping concentration of the first well region of the second pixel region is higher than the doping concentration of the first well region of the first pixel region.

3. The image sensor of claim 2, wherein the plurality of pixel regions comprises a third pixel region adjacent to the first pixel region, and the doping concentration of the first well region of the third pixel region is lower than the doping concentration of the first well region of the first pixel region.

4. The image sensor of claim 2, wherein the doping concentration of the first well region of the first pixel region has a difference of 10% to 20% compared to the doping concentration of the first well region of the second pixel region.

5. The image sensor of claim 1, wherein the thickness of the first well region of the second pixel region is greater than the thickness of the first well region of the first pixel region.

6. The image sensor of claim 5, wherein the plurality of pixel regions comprises a third pixel region adjacent to the first pixel region, and the thickness of the first well region of the third pixel region is smaller than the thickness of the first well region of the first pixel region.

7. The image sensor of claim 5, wherein a portion of the first well region of the second pixel region is in contact with a portion of the third well region of the second pixel region.

8. The image sensor of claim 1, wherein the doping concentration of the second well region of the second pixel region is higher than the doping concentration of the second well region of the first pixel region.

9. The image sensor of claim 8, wherein the plurality of pixel regions comprises a third pixel region adjacent to the first pixel region, and the doping concentration of the second well region of the third pixel region is lower than the doping concentration of the second well region of the first pixel region.

10. The image sensor of claim 1,
wherein each of the first pixel region and the second pixel region comprises
a light shielding portion disposed on a lower surface of the substrate and configured to block light from reaching the substrate, and
one or more opening regions configured to transmit light to the substrate, and
wherein a number of the one or more opening regions of the second pixel region is greater than a number of the one or more opening regions of the first pixel region.

11. The image sensor of claim 10, wherein the plurality of pixel regions comprises a third pixel region adjacent to the first pixel region, the third pixel region comprises a light shielding portion and one or more opening regions, and a number of the one or more opening regions of the third pixel region is less than the number of the one or more opening regions of the first pixel region.

12. The image sensor of claim 1, wherein the first pixel region comprises the light-receiving surface having a first uneven profile.

13. The image sensor of claim 12, wherein the second pixel region comprises the light-receiving surface having a second uneven profile, and a surface area of the light-receiving surface of the second pixel region is greater than a surface area of the light-receiving surface of the first pixel region.

14. The image sensor of claim 13, wherein the plurality of pixel regions comprises a third pixel region adjacent to the first pixel region, and the light-receiving surface of the third pixel region has an even profile.

15. The image sensor of claim 1, wherein each of the first pixel region and the second pixel region comprises the device isolation film, and a thickness of the device isolation film of the second pixel region is greater than a thickness of the device isolation film of the first pixel region.

16. The image sensor of claim 15, wherein a portion of the device isolation film of the second pixel region is in contact with a portion of the third well region of the second pixel region.

17. The image sensor of claim 1, wherein a width of the device isolation film of the second pixel region is greater than a width of the device isolation film of the first pixel region.

18. The image sensor of claim 17, wherein a first surface of the device isolation film of the second pixel region is in contact with a surface of the first impurity region of the second pixel region, and a second surface of the device isolation film is in contact with a surface of the second impurity region of the second pixel region.

19. An image sensor, comprising:
a pixel array comprising a plurality of pixel regions,
wherein the pixel array comprises:
a first pixel region group having a first sensitivity and comprising a plurality of first pixel regions of the plurality of pixel regions adjacent to each other;
a second pixel region group disposed adjacently to the first pixel region group and having a second sensitivity higher than the first sensitivity, the second pixel region group comprising a plurality of second pixel regions of the plurality of pixel regions adjacent to each other; and
a third pixel region group disposed adjacently to the first pixel region group and having a third sensitivity lower than the first sensitivity, the third pixel region group comprising a plurality of third pixel regions of the plurality of pixel regions adjacent to each other.

20. An image sensor, comprising:
a pixel array comprising a plurality of pixel regions; and
a peripheral circuit configured to drive the pixel array,
wherein the plurality of pixel regions comprise:
first pixel regions each including a first diode configured to generate electric charges in response to light of a first intensity;
second pixel regions each including a second diode configured to generate electric charges in response to light of a second intensity stronger than the first intensity; and
third pixel regions each including a third diode configured to generate electric charges in response to light of a third intensity weaker than the first intensity,
wherein the peripheral circuit is configured to generate image data based on the electric charges generated during a single frame period in the first pixel regions, the second pixel regions, and the third pixel regions.
